(19) United States
(12) Patent Application Publication
(10) Pub. No.: US 2009/0323260 A1
(43) Pub. Date: Dec. 31, 2009

(54) SLIDE AND CLICK COMBINATION SWITCH FOR A PERSONAL MEDIA PLAYER

(75) Inventors: Sung Ho Son, Redmond, WA (US); Chris Robert Towers, Seattle, WA (US); Carl Joseph Ledbetter, Mercer Island, WA (US)

Correspondence Address: MICROSOFT CORPORATION, ONE MICROSOFT WAY, REDMOND, WA, 98052, US

(73) Assignee: MICROSOFT CORPORATION, Redmond, WA (US)

(21) Appl. No.: 12/146,005

(22) Filed: Jun. 25, 2008

(51) Int. Cl. H05K 7/00; H01H 15/10

(52) U.S. Cl. 361/679.01; 200/547

(57) ABSTRACT

In a personal media player, a slide and click combination switch enables several operational functions to be integrated into a single interface. The operational functions include user control lock and power state management. The combination switch includes a button that is arranged to laterally slide between two discrete switch positions (locked and unlocked) as well as move axially between unactuated and actuated positions against a spring force that is normally biased towards the unactuated position. When the button in the combination switch is slid to the locked position, the button cannot be actuated, the user controls on the player are disabled, and the power status of the player (i.e., either on or off) is maintained in its current state. When the button is slid to the unlocked position, the user controls on the player are enabled, and the button may be actuated to implement different device power management scenarios.

### BACKGROUND

Personal media players such as MP3 (Moving Pictures Expert Group, MPEG-1, audio layer 3) players, and other devices like PDAs (personal digital assistants), mobile phones, smart phones, and the like typically enable users to interact with and consume media content such as music and video. Such players are generally compact and lightweight and operate on battery power to give users a lot of flexibility in choosing when and where to consume media content. As a result, personal media players have become widely accepted and used in all kinds of environments, including those where users are very active or out and about in their busy lifestyles. For example, when at the beach, a user might watch an episode of a favorite television show. The personal media player can then be placed in a pocket so that the user can listen to music while exercising, or when riding on the train back home.

Personal media players commonly provide a lock switch that when set to the ‘Locked’ position disables the user controls so that stray pushes or other activations are ignored. This can be a useful feature particularly when the player is being used on the go and could easily get bumped. In addition, if the personal media player is turned off when the switch is set to ‘Locked’, the player cannot be turned on accidentally and have its battery get run down. While current locking arrangements can often perform satisfactorily, additional features and functionalities would still be desirable.

This Background is provided to introduce a brief context for the Summary and Detailed Description that follow. This Background is not intended to be an aid in determining the scope of the claimed subject matter nor be viewed as limiting the claimed subject matter to implementations that solve any or all of the disadvantages or problems presented above.

### SUMMARY

In a personal media player, a slide and click combination switch enables several operational functions to be integrated into a single interface. In various illustrative examples, the operational functions include user control lock and power state management. The combination switch includes a button that is arranged to laterally slide between two discrete switch positions (locked and unlocked) as well as move axially between unactuated and actuated positions against a spring force that is normally biased towards the unactuated position. The button can thus be clicked by a user to provide a momentary contact, or be clicked and held in the actuated position. When the button is slid to the locked position, the button cannot be actuated, the user controls on the personal media player are disabled, and the power status of the player (i.e., either on or off) is maintained in its current state. When the button is slid to the unlocked position, the user controls on the player are enabled, and the button may be actuated to implement different device power management scenarios.

When the button is in the unlocked position and clicked, the power state of the personal media player may be toggled between ‘On’ and ‘Off.’ When the button is in the unlocked position, the use of the ‘Click’, and ‘Click and Hold’ features, enable the user to switch the personal media player between three power states including ‘On,’ ‘Off,’ and ‘Standby.’ In the ‘Standby’ state, the operations of the player will typically be minimal and the display screen will be deactivated. Manipulation of any user control on the player, or another click of the button in the combination switch will toggle the player back to the full ‘On’ power state from the ‘Standby’ state.

Advantageously, the present slide and click combination switch provides a compelling user interface that is intuitive and easy to use to control the locking and power management features in the player. In addition, combining multiple operational functions into a single control reduces control proliferation which is often important from both device packaging and aesthetic points of view.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### DESCRIPTION OF THE DRAWINGS

FIG. 1 shows an illustrative portable device usage environment where a user listens to audio content being rendered through earphones by a personal media player;

FIG. 2 shows an illustrative arrangement where a personal media player is inserted in a dock that is operatively coupled to a PC with a synchronization (“sync”) cable;

FIG. 3 shows an illustrative arrangement where a personal media player is being charged by a power adapter through the sync cable;

FIG. 4 shows details of an illustrative personal media player that utilizes the present slide and click combination switch;

FIGS. 5-7 show illustrative discrete switching positions that are supported by the slide and click combination switch;

FIG. 8 shows a first illustrative power management scenario for a personal media player that is enabled by the present slide and click combination switch;

FIG. 9 shows a second illustrative power management scenario for a personal media player that is enabled by the present slide and click combination switch;

FIG. 10 is a simplified block diagram that shows various functional components of an illustrative example of a personal media player; and

FIG. 11 is a simplified block diagram that shows various physical components of an illustrative example of a personal media player.

Like reference numerals indicate like elements in the drawings. Elements are not drawn to scale unless otherwise indicated.

### DETAILED DESCRIPTION

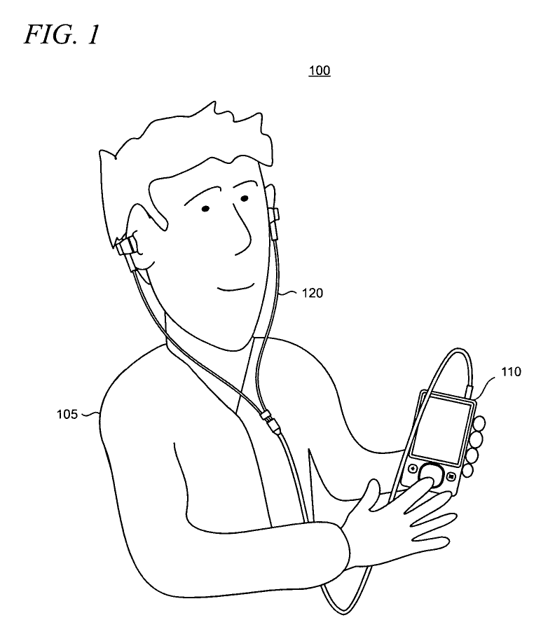

FIG. 1 shows an illustrative portable device usage environment 100 in which a user 105 interacts with digital media content rendered by a personal media player 110. In this example, the personal media player 110 is configured with capabilities to play audio content such as MP3 files or content from over-the-air radio stations, display video and photographs, and render other content. The user 105 will typically use earphones 120 to enable audio content, such as music or the audio portion of video content, to be consumed privately (i.e., without the audio content being heard by others) and at volume levels that are satisfactory for the user while maintaining good battery life in the personal media player. Earphones 120 are representative of a class of devices used to render audio which may also be known as headphones, earbuds, headsets, and by other terms. Earphones 120 generally will be configured with a pair of audio speakers (one for each ear), or less commonly a single speaker, along with a means to place the speakers close to the user's ears.

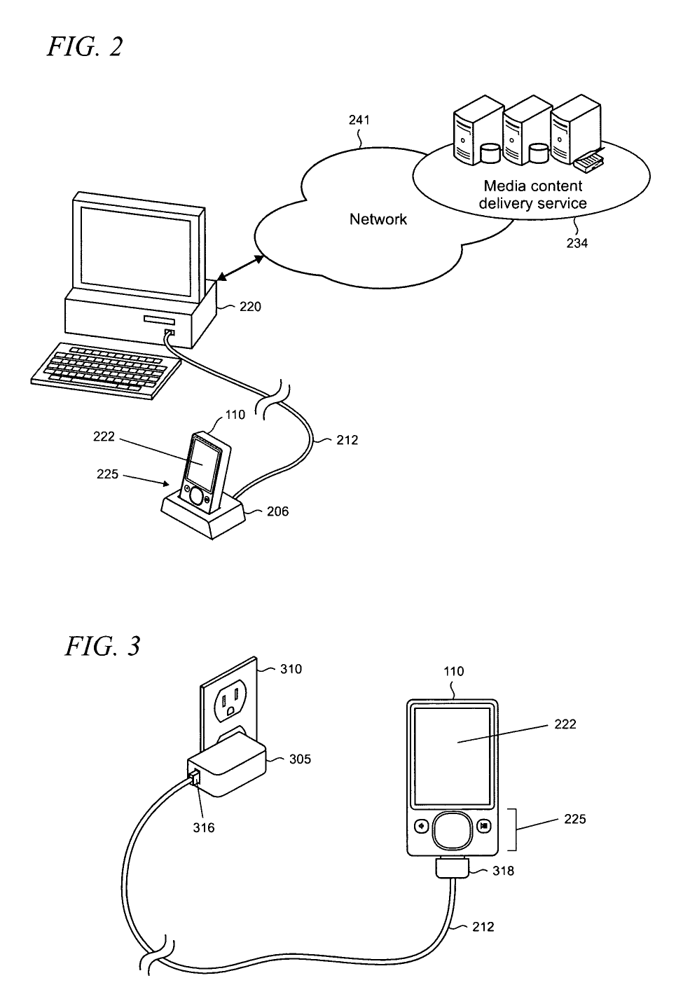

The usage environment 100 for portable devices commonly extends to a home or office environment when a device is being synchronized with other devices or being charged. For example, FIG. 2 shows the personal media player 110 inserted in a dock 206 that is operatively coupled to a PC 220 with a sync (i.e., synchronization) cable 212. Docking the personal media player 110 to the PC 220 typically enables them to operatively communicate, for example, to synchronize data and share media content. A pair of mating connectors are utilized to implement the connection between the personal media player 110 and the dock 206, where one of the connectors in the pair is disposed in the player and the other is disposed in the recess of the dock 206 in which the player sits.

The dock 206 also typically provides a charging functionality to charge an onboard battery in the personal media player 110 when it is docked. It is noted that the sync cable 212 may also be directly coupled to the personal media player 110 (i.e., without the player being inserted into the dock 206). However, the dock 206 may generally be used to position the docked personal media player 110 into a convenient position so that the player's display 222 may be easily seen and the controls 225 readily accessed by the user 105.

The synchronization process implemented between the PC 220 and the personal media player typically enables media content such as music, video, images, games, information, and other data to be selected by a user and then downloaded from an on-line source or media content delivery service 234 over a network 241 such as the Internet to the PC 220. The downloaded media content can then be transferred and stored in the docked media player shuttle. In this way, the PC 220 operates as an intermediary or proxy device between the service 234 and the personal media player 110.

FIG. 3 shows the personal media player 110 being directly coupled to the sync cable 212. In this example, the sync cable 212 is coupled to an AC power adapter 305 that converts the AC power from a wall outlet 310 into DC power that is typically used to recharge the player's onboard rechargeable battery. Accordingly, in many implementations the sync cable 212 is designed to be removably couplable to the various devices in the environment 100 using connectors that are disposed at each end of the sync cable. For example, the end of the sync cable 212 that connects to the AC power adapter 305 and PC 220 may use a standardized connector 316 such as one configured in accordance with USB (Universal Serial Bus) or IEEE-1394 (Institute of Electrical and Electronics Engineers). The other end of the sync cable 212 will typically use a device-specific connector 318 that mates with a corresponding connector that is disposed in the personal media player 110 and/or the dock 206.

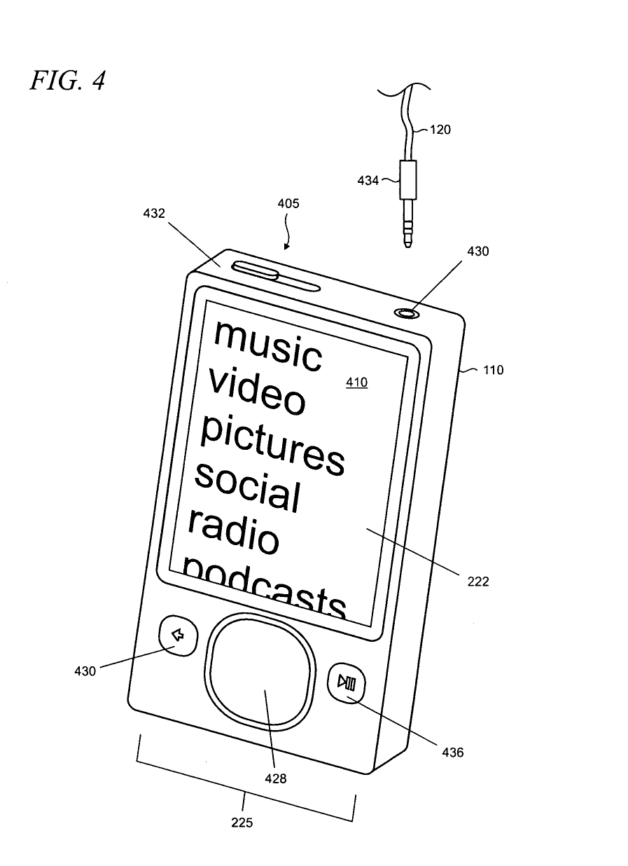

FIG. 4 shows details of the illustrative personal media player 110 including a slide and click combination switch 405. The personal media player 110 typically uses a graphical user interface (“GUI”) 410 that is rendered on the display screen 222, as well as user controls 225. The GUI 410 uses menus, icons, and the like to enable the user 105 to find, select, and control playback of media content that is available to the player 110. In addition to supporting the GUI 410, the display screen 222 is also used to render video content, typically by turning the player 110 to a landscape orientation so that the long axis of the display screen 222 is parallel to the ground.

The user controls 225, in this example, include a gesture pad 428, called a G-Pad, which combines the functionality of a conventional directional pad (i.e., a “D-pad”) with a touch sensitive surface as described in U.S. Patent Application Ser. No. 60/987,399, filed Nov. 12, 2007, entitled “User Interface with Physics Engine for Natural Gestural Control,” owned by the assignee of the present application and hereby incorporated by reference in its entirety having the same effect as if set forth in length. A “back” button 430 and a “play/pause” button 436 are also provided. However, other types of user controls may also be used depending on the requirements of a particular implementation. The user 105 will manipulate the user controls 225 to make selections of media content, control operation of the personal media player 110, set preferences, and the like through the GUI 410.

An audio jack 430 is located on the top of the body 432 of the personal media player 110. The audio jack 430 interfaces with a corresponding plug 434 that is located at the end of the earphones 120.

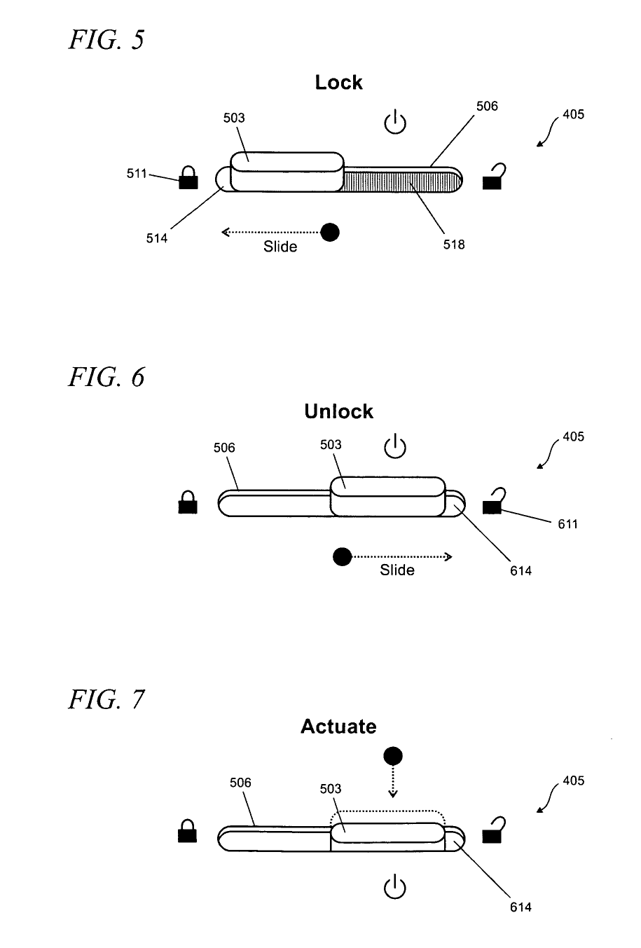

FIGS. 5-7 show illustrative discrete switching positions that are supported by the slide and click combination switch 405. The slide and click combination switch 405 is arranged as an electromechanical assembly that includes components that produce different electrical signals depending on the state of switch 405. In particular, the switch 405 comprises a button 503 that is arranged to slide laterally in a linear motion through a switch carrier (not shown) that constrains the lateral, linear motion and positions the button within a slot 506 that is disposed in the top surface of the body 432 of the personal media player 110 in this example. However, it is emphasized that the slide and click combination switch 405 may be located in other positions on the body of player 110 as well depending on the requirements of a particular implementation.

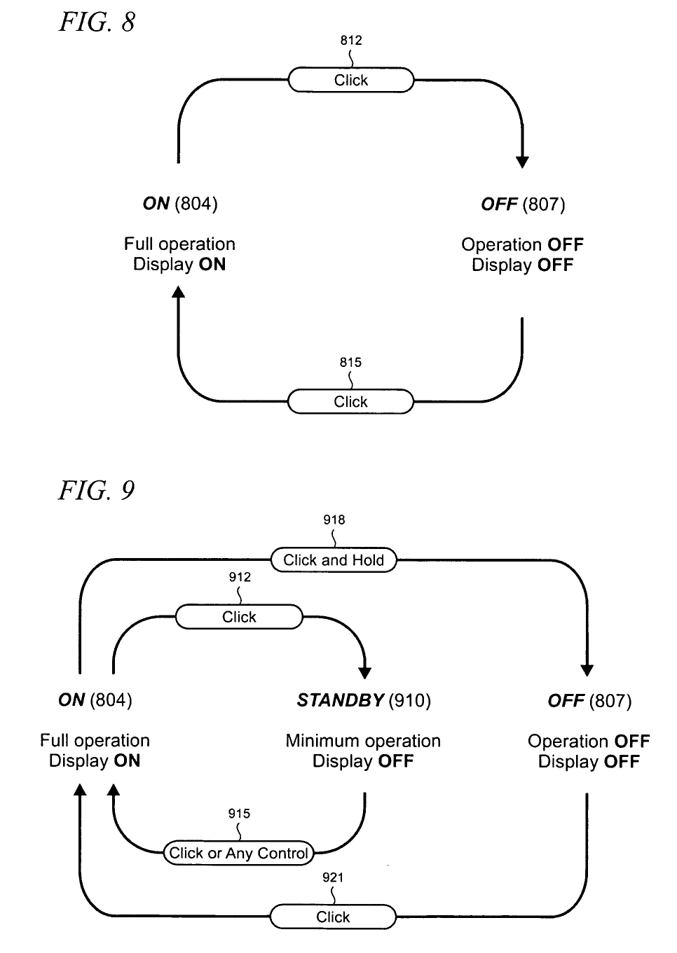

In addition to lateral linear motion within the slot 506, the button 503 may be actuated, in some cases, along an axial motion path. The button 503 is provided with a spring force that is normally biased in an unactuated position, which in this example, is in an upward position for the button 503. The button 503 can thus be actuated by the user 105 to provide a momentary contact in a ‘Click’ mode, or be utilized in a ‘Click and Hold’ mode where the button is held by the user in the actuated (i.e., down) position for a period of time such as a second or two (i.e., non-momentary contact). Use of these actuation modes is discussed below in the power management scenarios shown in FIGS. 8 and 9 and discussed in the accompanying text. In some implementations, the button 503 may be arranged to provide an audible clicking sound and/or tactile feedback sensation to the user 105 when it is actuated.

It is noted that the total axial excursion of the button 503 in the slide and click combination switch 405 can vary by implementation. In addition, the position of the button in its unactuated (i.e., ‘up’) position with respect to the top surface of the personal media player 110 may also vary. In some cases, for example, it may be desirable to set the unactuated position of the button 503 so that it has a relatively low profile with respect to the player 110.

The button 503 is arranged to laterally slide between two discrete switch positions (i.e., switch states) that are located at either end of the button's travel path in the slot 506. In this particular example as shown in FIG. 5, the left end of the slot 506 is used as a ‘Locked’ switch position as indicated by a lock icon 511. The lock icon 511 is typically marked on the surface of the personal media player 110 to identify the ‘Locked’ switch position to the user 105 (as indicated by reference numeral 514 in FIG. 5). In addition, a colored indicator 518, which may be any color but is typically red, can be exposed in the slot 506 as an additional identification for the ‘Locked’ switch position 514.

When the user 105 slides the button 503 to the ‘Locked’ switch position 514, the slide and click combination switch 405 can interact through an interface in the player 110 to implement locking functionality in the player 110. Illustratively, the locking functionality includes disabling the user controls 225 and maintaining the power status of the player 110 in its current state. For example, if the player 110 is turned on and operating when the user 105 slides the button 503 to the ‘Locked’ switch position 514, the player will stay on and continue operating (for example, by playing successive songs in a playlist) and any attempted actuations of the user controls 225 will be ignored.

Likewise, if the personal media player 110 is off and not operating when the user 105 slides the button 503 to the ‘Locked’ switch position 514, the player will stay off even if the user controls 225 are manipulated. Locking the player 110 can be helpful to prevent the onboard battery from being run down inadvertently when the player is being stored, for example in a pocket or backpack, where the user controls 225 are exposed and could be actuated unintentionally. In addition, when the button 503 is slid to the ‘Locked’ position 514, it cannot be clicked (i.e., actuated axially downward).

FIG. 6 shows the button 503 when slid to right hand end of the slot 506. In this position, an ‘Unlocked’ switch position is implemented as indicated by reference numeral 614. As shown, an unlocked icon 611 is used to indicate to the user the ‘Unlocked’ switch position 614 and the color indicator is no longer exposed. When the button 503 is in the ‘Unlocked’ switch position 614 in this illustrative example, the user controls 225 on the personal media player 110 are enabled and the button 503 may be actuated, as shown in FIG. 7, to implement different device power management scenarios.

FIG. 8 shows a first illustrative power management scenario that may be implemented using the slide and click combination switch 405 on the personal media player 110. In this scenario, when the button 503 in slide and click combination switch 405 is in the ‘Unlocked’ switch position 614, actuation of the button will switch the personal media player 110 between two power states, ‘On’ and ‘Off’. In the ‘On’ power state, as indicated by reference numeral 804, full operation of the player 110 is enabled and the display 222 is turned on to display the GUI 410 or render video content. In the ‘Off’ power state, as indicated by reference numeral 807, player operations and the display 222 are off. Accordingly, if the player 110 is in the ‘On’ state 804, a ‘Click’ (i.e., a momentary actuation) of the button 503 by the user 105, as indicated by reference numeral 812, will switch the player 110 to the ‘Off’ state 807. Similarly, a ‘Click’ of the button 503, as indicated by reference numeral 815, will switch the player 110 from the ‘Off’ state 807 to the ‘On’ state 804.

FIG. 9 shows a second illustrative power management scenario that may be implemented using the slide and click combination switch 405 on the personal media player 110. In this scenario, both the ‘Click’ and ‘Click and Hold’ modes of actuation may be used to switch the player 110 between three states including ‘On’, ‘Off’ and ‘Standby’ which are respectively indicated by reference numerals 804, 807, and 910. When the player 110 is in the ‘On’ power state 804, a ‘Click’ 912 of the button 503 will switch the player to the ‘Standby’ power state 910. In the ‘Standby’ power state 910, the operations of the player 110 will be minimized and the display 222 turned off.

With such minimized operations, the player 110 will suspend currently playing media content, but will not shut down. Instead, readiness will be maintained to resume full operations by another ‘Click’ 915 of the button 503 which switches the player 110 back to the ‘On’ state 804. In addition to using the button 503, the activation of any user control 225 will also switch the player 110 from ‘Standby’ to ‘On.’ When back in the ‘On’ power state 804, the display 222 is turned back on and the suspended playback of media content will be resumed. Use of the ‘Standby’ power state 910 will advantageously help to preserve battery power while eliminating the boot up time that is normally required when the personal media player 110 is started from the fully ‘Off’ power state 807.

If the player 110 is in the ‘On’ power state 804 and a ‘Click and Hold’ operation is performed by the user 105 using the button 503 as indicated by reference numeral 918, then the personal media player 110 will be switched to the ‘Off’ power state 807. The amount of time that the button 503 needs to be actuated to disambiguate a ‘Click’ from a ‘Click and Hold’ can vary. Typically if the button is actuated and held in a down position for several seconds the action will be recognized as a ‘Click and Hold’ operation.

As with the first illustrative scenario shown in FIG. 8 and described in the accompanying text, the user 105 may perform a ‘Click’ 921 using the button 503 to switch the personal media player 110 from the ‘Off’ power state 807 to the ‘On’ power state 804.

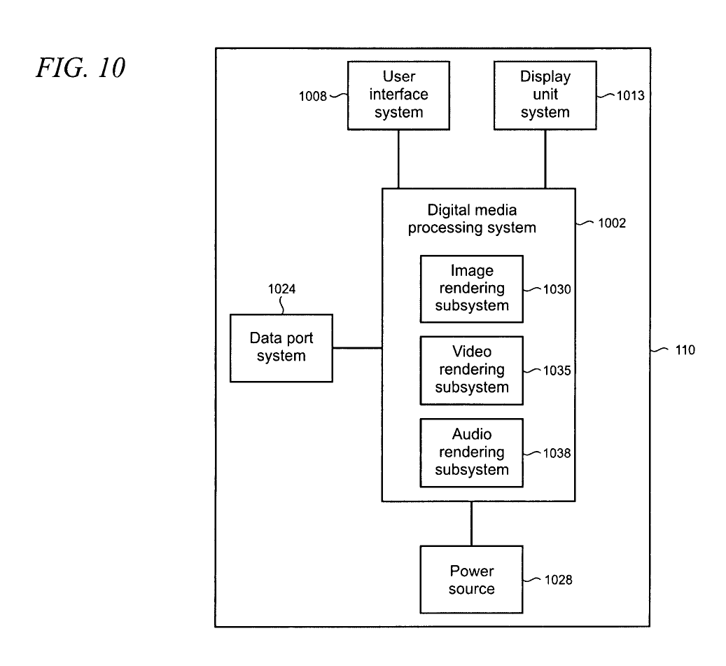

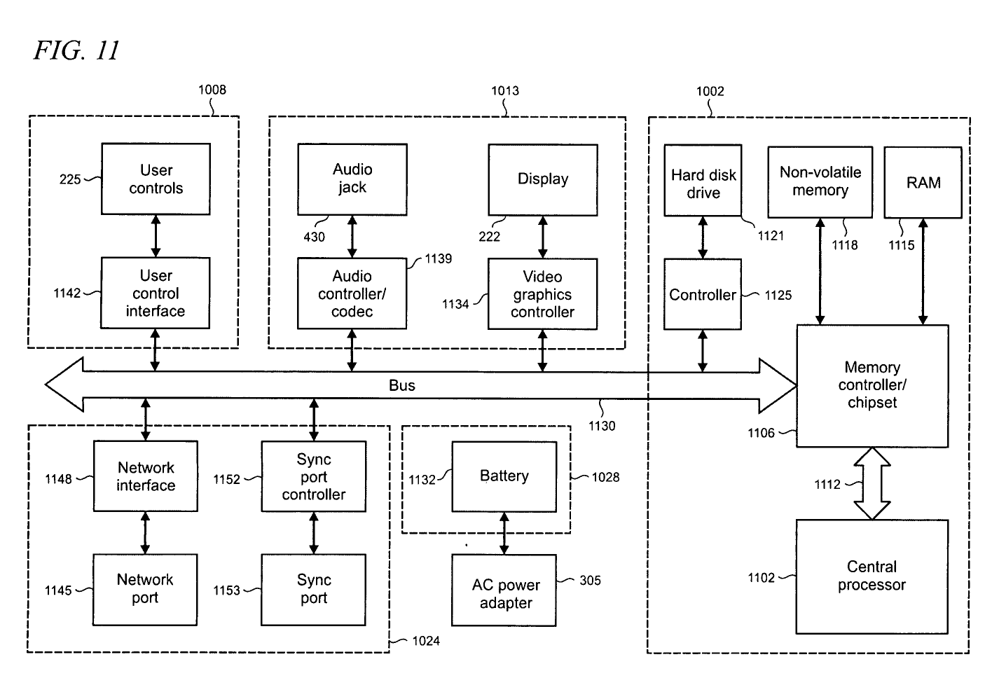

FIG. 10 a simplified block diagram that shows various illustrative functional components of the personal media player 110. The functional components include a digital media processing system 1002, a user interface system 1008, a display unit system 1013, a data port system 1024, and a power source system 1028. The digital media processing system 1002 further comprises an image rendering subsystem 1030, a video rendering subsystem 1035, and an audio rendering subsystem 1038.

The digital media processing system 1002 is the central processing system for the personal media player 110 and provides functionality that is similar to that provided by the processing systems found in a variety of electronic devices such as PCs, mobile phones, PDAs, handheld game devices, digital recording and playback systems, and the like.

Some of the primary functions of the digital media processing system 1002 may include receiving media content files downloaded to the player 110, coordinating storage of such media content files, recalling specific media content files on demand, and rendering the media content files into audio/visual output on the display for the user 105. Additional features of the digital media processing system 1002 may also include searching external resources for media content files, coordinating DRM (digital rights management) protocols for protected media content, and interfacing directly with other recording and playback systems.

As noted above the digital media processing system 1002 further comprises three subsystems: the video rendering subsystem 1035 which handles all functionality related to video-based media content files, which may include files in MPEG (Moving Picture Experts Group) and other formats; the audio rendering subsystem 1038 which handles all functionality related to audio-based media content including, for example music in the commonly-utilized MP3 format and other formats; and the image rendering subsystem 1030 which handles all functionality related to picture-based media content, including for example JPEG (Joint Photographic Experts Group), GIF (Graphic Interchange Format), and other formats. While each subsystem is shown as being logically separated, each may in fact share hardware and software components with each other and with the rest of the personal media player 110, as may be necessary to meet the requirements of a particular implementation.

Functionally coupled to the digital media processing system 1002 is the user interface system 1008 through which the user 105 may exercise control over the operation of the personal media player 110. A display unit system 1013 is also functionally coupled to the digital media processing system 1002 and may comprise the display screen 222 (FIG. 2). Audio output through the audio jack 430 (FIG. 4) for playback of rendered media content may also be supported by display unit system 1013. The display unit system 1013 may also functionally support and complement the operation of the user interface system 1008 by providing visual and/or audio output to the user 105 during operation of the player 110.

The data port system 1024 is also functionally coupled to the digital media processing system 1002 and provides a mechanism by which the personal media player 110 can interface with external systems in order to download media content. The data port system 1024 may comprise, for example, a data synchronization connector port, a network connection (which may be wired or wireless), or other means of connectivity.

The personal media player 110 has a power source system 1028 that provides power to the entire device. The power source system 1028 in this example is coupled directly to the digital media processing system 1002 and indirectly to the other systems and subsystems throughout the player. The power source system 1028 may also be directly coupled to any other system or subsystem of the personal media player 110. Typically, the power source may comprise a battery, a power converter/transformer, or any other conventional type of electricity-providing power source, personal or otherwise.

FIG. 11 is a simplified block diagram that shows various illustrative physical components of the personal media player 110 based on the functional components shown in FIG. 10 and described in the accompanying text (which are represented in FIG. 11 by dashed lines) including the digital media processing system 1002, the user interface system 1008, the display unit system 1013, the data port system 1024, and the power source system 1028. While each physical component is shown as included in only a single functional component in FIG. 11 the physical components may, in fact, be shared by more than one functional component.

The physical components include a central processor 1102 coupled to a memory controller/chipset 1106 through, for example, a multi-pin connection 1112. The memory controller/chipset 1106 may be, in turn, coupled to random access memory (“RAM”) 1115 and/or non-volatile memory 1118 such as solid-state or Flash memory. These physical components, through connectivity with the memory controller/chipset 1106, may be collectively coupled to a hard disk drive 1121 (or other solid-state memory) via a controller 1125, as well as to the rest of the functional component systems via a system bus 1130.

In the power supply system 1028, a rechargeable battery 1132 may be used to provide power to the components using one or more connections (not shown). The battery 1132, in turn, may also be coupled to the external AC power adapter 305 (FIG. 3) or receive power via the sync cable 212 when it is coupled to the PC 220 (FIG. 2).

The display screen 222 is associated with a video graphics controller 1134. The video graphics controller will typically use a mix of software, firmware, and/or hardware, as is known in the art, to implement the GUI on the display screen 222. Along with the audio jack 430 and its associated audio controller/codec 1139, these components comprise the display unit system 1013 and may be directly or indirectly connected to the other physical components via the system bus 1130.

The user controls 225 are associated with a user control interface 1142 in the user interface system 1008 that implements the user control functionality that is used to support the interaction with the GUI as described above. A network port 1145 and associated network interface 1148, along with the sync port 1153 and its associated controller 1152 may constitute the physical components of the data port system 1024. These components may also directly or indirectly connect to the other components via the system bus 1130.

It will be appreciated that the principles of the present slide and click combination switch may be generally applied to other devices beyond media players. Such devices include, for example, mobile phones, PDAs, smart phones, handheld game devices, ultra-mobile computers, devices including various combinations of the functionalities provided therein, and the like.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed is:

1. A personal media player, comprising:
a body arranged for housing a digital media processing system and a display screen, the digital media processing system interfacing with the display screen to render digital media content in a form of images or video and interfacing with an audio interface to render digital media content in a form of audio;
one or more user controls operatively coupled to the digital media processor and located on the body for manipulation by a user; and
an electromechanical switch disposed on a surface of the body, the switch including a button that is arranged for i) axial actuation by the user between two axially located switch positions and ii) lateral slideable motion between two laterally located switch positions, the axially located switch positions and laterally located switch positions being usable to switch the personal media player between power states.

2. The personal media player of claim 1 in which the button is normally biased against a spring force in an unactuated axial position to support a ‘Click’ mode of operation in which the button is actuated with a momentary contact and a ‘Click and Hold’ mode of operation in which the button is actuated with a non-momentary contact.

3. The personal media player of claim 2 in which the axial actuation of the button is prevented when the button is in one of the two laterally located switch positions.

4. The personal media player of claim 1 in which the one or more user controls are disabled and a current power state is maintained when the button is in one of the two laterally located switch positions.

5. The personal media player of claim 1 in which the power states include an ‘On’ power state and an ‘Off’ power state, the ‘On’ power state being configured to fully enable all operations of the personal media player including operation of the display screen, and the ‘Off’ power state being configured to terminate all operations of the personal media player including operation of the display screen.

6. The personal media player of claim 5 in which the power states further include a ‘Standby’ state that is configured to enable a subset of the full operations of the personal media player and turn off the display screen.

7. The personal media player of claim 6 in which a ‘Click’ operation switches a power state from ‘On’ to ‘Standby’.

8. The personal media player of claim 6 in which a ‘Click and Hold’ operation switches a power state from ‘On’ to ‘Off’.

9. The personal media player of claim 6 in which a ‘Click’ operation or use of any of the one or more user controls switches a power state from ‘Standby’ to ‘On’.

10. The personal media player of claim 1 in which the switch is arranged to produce audible feedback to the user when the switch is either laterally actuated or axially actuated.

11. The personal media player of claim 1 in which the switch is arranged to provide tactile feedback to the user when the switch is either laterally actuated or axially actuated.

12. An electromechanical switch arranged for switching an electronic device between power states, comprising:
a switch carrier for constraining lateral motion of switching elements between two laterally located switch positions; and
a button functioning as a switching element that interoperates with the switch carrier, the button being arranged for slideable movement, responsively to actuation by a user, between the two laterally located switch positions, the button being further arranged for actuation between two axially located switch positions when the button is in one of the two laterally located switch positions, the button being normally biased against a spring force in an unactuated axial position to support a ‘Click’ mode of operation, in which the button is actuated with a momentary contact, and a ‘Click and Hold’ mode of operation, in which the button is actuated with a non-momentary contact, the ‘Click’ and ‘Click and Hold’ modes of operation being usable to implement the power state switching for the electronic device.

13. The electromechanical switch of claim 12 in which the electronic device is one of mobile phone, PDA, personal media player, handheld game device, smart phone, ultra-mobile computer, portable electronic device, or a device having a combination of functionalities provided therein.

14. The electromechanical switch of claim 12 in which the power states include at least one of ‘On’, ‘Off’, and ‘Standby’, the ‘On’ power state being configured to fully enable all operations of the electronic device, and the ‘Off’ power state being configured to terminate all operations of the electronic device, and the ‘Standby’ power state being configured to temporarily suspend operations of the electronic device, the electronic device being switchable between the ‘Standby’ power state and ‘On’ power state without being restarted.

15. The electromechanical switch of claim 12 in which the two laterally located switch positions comprise a locked switch position and an unlocked switch position.

16. The electromechanical switch of claim 15 in which the electronic device includes user controls that are disabled when the button is in the locked switch position.

17. The electromechanical switch of claim 15 in which the electronic device is maintained in its current power state when the button is in the locked switch position.

18. A method for enabling user control over operation of a personal media player, the method comprising the steps of:
providing a personal media player to the user, the personal media player being configured to render digital media content including audio and video responsively to user manipulation of user controls that are disposed on the personal media player;
enabling selectable disablement of the user controls through manipulation of a slideable and clickable button in a switch that is exposed on the personal media player to the user, the slideable and clickable button being laterally moveable between a locked switching position and an unlocked switching position, the user controls being disabled when the button is in the locked switching position; and
enabling selectable switching between three power states, the power states including ‘On’, ‘Off’ and ‘Standby’ through user manipulation of the button in an axial motion from an unactuated position to an actuated position when the button is in the unlocked switching position.

19. The method of claim 18 in which the power state is switched from ‘On’ to ‘Standby’ when the button is actuated using momentary contact.

20. The method of claim 18 in which the power state is switched from ‘On’ to ‘Off’ when the button is held in the actuated position.
